(19) United States
(12) Patent Application Publication
(10) Pub. No.: US 2021/0059063 A1
(43) Pub. Date: Feb. 25, 2021

(54) MAGNETIC ATTRACTION TYPE ELECTRONIC BUILDING BLOCK CONSTRUCTION MODULE AND MANUFACTURING METHOD THEREOF

(71) Applicant: SHENZHEN ZHINENGPAI TECHNOLOGY CO., LTD., SHENZHEN (CN)

(72) Inventor: Yingsheng HONG, SHENZHEN (CN)

(73) Assignee: SHENZHEN ZHINENGPAI TECHNOLOGY CO., LTD.

(21) Appl. No.: 16/562,448

(22) Filed: Sep. 6, 2019

(30) Foreign Application Priority Data
Aug. 22, 2019 (CN) 201910776737.5

(51) Int. Cl. H05K 5/02; H05K 5/00

(52) U.S. Cl. CPC H05K 5/0256; H05K 5/0021

(57) ABSTRACT

The magnetic attraction type electronic building block construction module includes a circuit board. A spring needle holder is installed on the circuit board; the spring needle holder includes a spring female needle holder and a spring male needle holder; upper ends of the spring female needle holder and the spring male needle holder are provided with needle holder protrusions; a bottom plate is installed on the bottom of the spring needle holder; bottom plate upper protrusions are installed around the bottom plate; magnet grooves are formed in the upper surfaces of the bottom plate upper protrusions; magnets are installed in the magnet grooves; a structural element is installed on the upper end of the circuit board; and second connecting protrusions matched with the magnet grooves are installed on the bottom of the structural element. This connection mode reduces the process complexity and is easy to realize automatic production.

### CROSS-REFERENCE TO RELATED APPLICATIONS

This application claims priority to Chinese Patent Application No. 201910776737.5 with a filing date of Aug. 22, 2019. The content of the aforementioned applications, including any intervening amendments thereto, are incorporated herein by reference.

### TECHNICAL FIELD

The present invention relates to the technical field of circuit components, in particular to a magnetic attraction type electronic building block construction module and a manufacturing method thereof.

### BACKGROUND OF THE PRESENT INVENTION

As technical and actual demands increase, the combination of electronic building modules with circuits and mechanical structures to form more complex products has become a demand in the prior art. For example, in the field of toys or education, the demand already exists. Different circuit boards and different mechanical modules are combined together through the connection units of the electronic building modules to form a system with more complex functions, which has practical value for learning the working principle of the circuits, or designing some products including circuit modules and mechanical modules, or making some creative products.

The existing electronic building module has the following disadvantages: 1. The manufacturing process of the electronic building module in the prior art is complicated, and especially, the assembly connection between the circuit unit and the connecting unit depends on a large amount of welding work. The welding work is generally completed by people, which affects the production efficiency of the electronic building system. Moreover, the manufacture of the circuit module in the electronic building system has high requirements for production personnel, and is easy to produce an increased proportion of defective products and waste. 2. The combination strength between a circuit connector and the circuit board in an electronic building system of the prior art is insufficient, causing poor use experience. 3. After the existing module technology is completed, it is easy to generate a large number of tolerances, which is inconvenient to use.

### SUMMARY OF PRESENT INVENTION

The purpose of the present invention is to provide a magnetic attraction type electronic building block construction module and a manufacturing method thereof, so as to solve the problems proposed in the above background.

To achieve the above purpose, the present invention provides the following technical solution:

A magnetic attraction type electronic building block construction module comprises a circuit board, wherein the circuit board comprises a circuit board body; the circuit board body is provided with a connecting hole; a spring needle holder is installed on the bottom of the circuit board; the spring needle holder comprises a spring female needle holder and a spring male needle holder; upper ends of the spring female needle holder and the spring male needle holder are fixedly provided with needle holder protrusions matched with the connecting hole; a bottom plate is installed on the bottom of the spring needle holder; the bottom plate comprises a bottom plate body; bottom plate upper protrusions are fixedly installed around the upper surface of the bottom plate body; magnet grooves are formed in the upper surfaces of the bottom plate upper protrusions; magnets are installed in the magnet grooves; a structural element is installed on the upper end of the circuit board; the structural element comprises a structural element body; and second connecting protrusions matched with the magnet grooves are fixedly installed on the bottom of the structural element body.

As a further technical solution of the present invention: needle holes are formed in the spring female needle holder and the spring male needle holder; spring female needles matched with the needle holes are installed in the needle holes of the spring female needle holder; and spring male needles matched with the needle holes are installed in the needle holes of the spring male needle holder.

As a further technical solution of the present invention: the spring needle holder is welded with the circuit board.

As a further technical solution of the present invention: the structural element and the bottom plate are made of plastic.

As a further technical solution of the present invention: the structural element and the bottom plate are connected through ultrasonic welding.

As a further technical solution of the present invention: a connecting interface is arranged on a side surface of the structural element body.

As a further technical solution of the present invention: the upper end of the structural element body is also fixedly provided with first connecting protrusions; bottom plate lower protrusions are fixedly installed around the bottom of the bottom plate body; and grooves matched with the first connecting protrusions are formed at the bottoms of the bottom plate lower protrusions.

A manufacturing method of the magnetic attraction type electronic building block construction module comprises the following steps:

step I. selecting a matching component according to a design size;

step II. inserting the spring female needle and the spring male needle into the needle holes of the spring female needle holder and the spring male needle holder respectively; then inserting the needle holder protrusions on the spring female needle holder and the spring male needle holder into the connecting hole on the circuit board; and then welding and fixing; and

step III. putting magnets into the magnet grooves; then putting the circuit board welded in step II onto the bottom plate; and finally, inserting the second connecting protrusions at the bottom of the structural element into the magnet grooves, and welding and fixing by an ultrasonic welding machine.

Compared with the prior art, the present invention has the beneficial effects: the function of a magnetic attraction structure can be realized by installing the assembled building block construction module. This connection mode is extremely convenient for installation and production, reduces the process complexity and is easy to realize automatic production; and the whole structure can reduce the production cost.

### DESCRIPTION OF THE DRAWINGS

FIG. 1 is a structural schematic diagram of a magnetic attraction type electronic building block construction module;

FIG. 2 is a structural schematic diagram of a structural element in a magnetic attraction type electronic building block construction module;

FIG. 3 is a structural schematic diagram of a circuit board in a magnetic attraction type electronic building block construction module;

FIG. 4 is a structural schematic diagram of a spring needle holder in a magnetic attraction type electronic building block construction module; and

FIG. 5 is a structural schematic diagram of a bottom plate in a magnetic attraction type electronic building block construction module.

In the figures: 1—structural element; 2—circuit board; 3—spring needle holder; 4—bottom plate; 11—structural element body; 12—first connecting protrusion; 13—second connecting protrusion; 14—connecting interface; 21—circuit board body; 22—connecting hole; 31—spring female needle holder; 32—spring male needle holder; 33—needle hole; 34—spring male needle; 35—needle holder protrusion; 36—spring female needle; 41—bottom plate body; 42—bottom plate upper protrusion; 43—bottom plate lower protrusion; 44—magnet groove; and 45—magnet.

### DETAILED DESCRIPTION OF PREFERRED EMBODIMENTS

It should be understood in the description of the present invention that terms such as “central”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential”, etc. indicate direction or position relationships shown based on the drawings, and are only intended to facilitate the description of the present invention and the simplification of the description rather than to indicate or imply that the indicated device or element must have a specific direction or constructed and operated in a specific direction, and therefore, shall not be understood as a limitation to the present invention.

In addition, the terms such as “first” and “second” are only used for the purpose of description, rather than being understood to indicate or imply relative importance or hint the number of indicated technical features. Thus, the feature limited by “first” and “second” can explicitly or impliedly comprise one or more features. In the explanation of the present invention, the meaning of “a plurality of” is two or more unless otherwise clearly specified.

In the present invention, unless otherwise specifically regulated and defined, terms such as “installation”, “connected”, “connecting”, “fixation”, etc. shall be understood in broad sense, and for example, may refer to fixed connection or detachable connection or integral connection, may refer to mechanical connection or electrical connection, and may refer to direct connection or indirect connection through an intermediate medium or inner communication of two elements or interaction relationship of two elements. For those ordinary skilled in the art, the specific meanings of the above terms in the present invention may be understood according to concrete conditions.

Technical solutions in embodiments of the present invention will be clearly and fully described below in combination with drawings in embodiments of the present invention.

### Embodiment 1

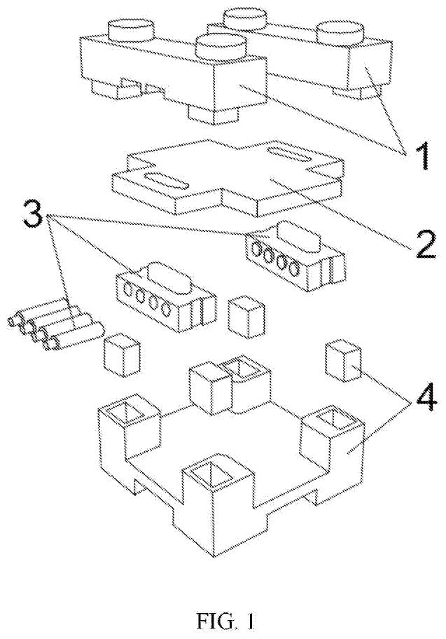

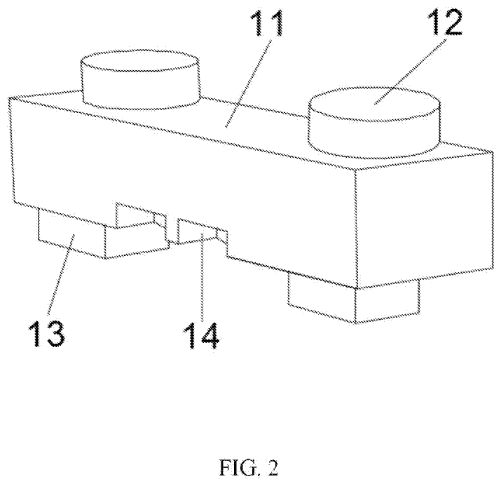

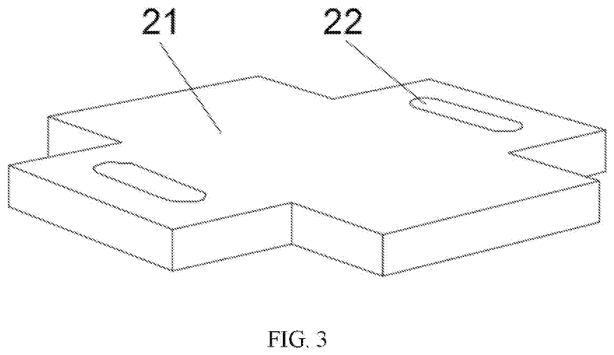

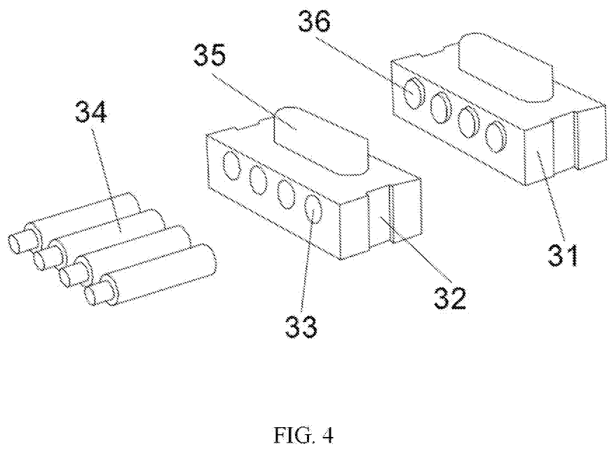

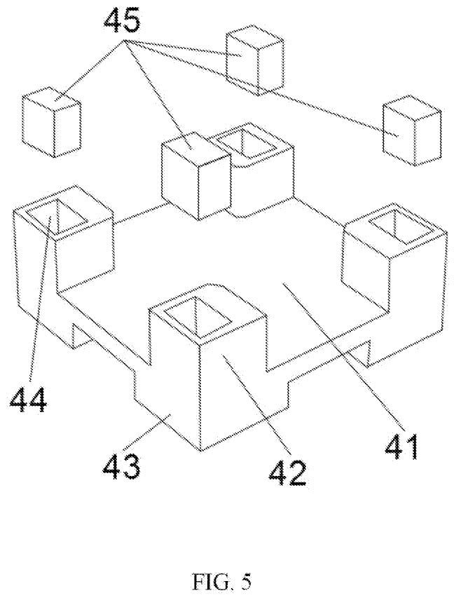

A magnetic attraction type electronic building block construction module shown in FIG. 1 to FIG. 5 comprises a circuit board 2. The circuit board 2 comprises a circuit board body 21. The circuit board body 21 is provided with connecting holes 22 which are specifically two through holes arranged up and down and symmetrically disposed about the circuit board body 21. A spring needle holder 3 is installed on the bottom of the circuit board 2. The spring needle holder 3 comprises a spring female needle holder 31 and a spring male needle holder 32. Specifically, needle holes 33 are formed in the spring female needle holder 31 and the spring male needle holder 32. Spring female needles 36 matched with the needle holes 33 are installed in the needle holes 33 of the spring female needle holder 31. Spring male needles 34 matched with the needle holes 33 are installed in the needle holes 33 of the spring male needle holder 32. The needle holes 33 in two needle holders are horizontally arranged and are at the same level, so as to ensure the stability of electrical connection after connection. Upper ends of the spring female needle holder 31 and the spring male needle holder 32 are fixedly provided with needle holder protrusions 35 matched with the connecting holes 22. The two needle holders are installed on the bottom of the circuit board 2 through the matching between the protrusions 35 and the connecting holes 22. Further, to improve the connection stability, the spring needle holder 3 is welded with the circuit board 2. A bottom plate 4 is installed on the bottom of the spring needle holder 3. The bottom plate 4 comprises a bottom plate body 41. Bottom plate upper protrusions 42 are fixedly installed around the upper surface of the bottom plate body 41, and specifically, fixedly installed at four corners, and preferably, integrally formed. A space formed inside is matched with a structure after combination of the circuit board 2 and the spring needle holder 3, which is convenient for fixedly installing the circuit board 2 and the spring needle holder 3 on the bottom plate 4. Magnet grooves 44 are formed in the upper surfaces of the bottom plate upper protrusions 42. Magnets 45 are installed in the magnet grooves 44. Magnetic attraction is conducted through the matching of the magnets 45, and attention should be paid to the direction of magnetic attraction during installation. A structural element 1 is installed on the upper end of the circuit board 2. The structural element 1 comprises a structural element body 11. Second connecting protrusions 13 matched with the magnet grooves 44 are fixedly installed on the bottom of the structural element body 11. Connection between the structural element 1 and the bottom plate 4 is realized through the matching between the second connecting protrusions 13 and the magnet grooves 44. To ensure insulation, the structural element 1 and the bottom plate 4 are made of plastic. At the same time, to further improve the overall stability and strength, the structural element 1 and the bottom plate 4 are connected through ultrasonic welding.

### Embodiment 2

The present embodiment is further optimized on the basis of Embodiment 1. A connecting interface 14 is arranged on a side surface of the structural element body 11, which is convenient for left-right (transverse) connection with other assembled magnetic attraction type electronic building block construction modules from the side surface (the interface has electrical characteristics), so as to achieve the effect of connection with other magnetic attraction type electronic building block construction modules.

The upper end of the structural element body 11 is also fixedly provided with first connecting protrusions 12; bottom plate lower protrusions 43 are fixedly installed around the bottom of the bottom plate body 41; and grooves matched with the first connecting protrusions 12 are formed at the bottoms of the bottom plate lower protrusions 43. The first connecting protrusions 12 are installed on the upper end of the structural element 1 and matched with the grooves at the bottom of the bottom plate 4, which is convenient for up-down (longitudinal) connection (mechanical structural connection) with other assembled magnetic attraction type electronic building block construction modules.

The present embodiment also provides a manufacturing method of the magnetic attraction type electronic building block construction module, comprising the following steps:

step I. selecting a matching component according to a design size;

step II. inserting the spring female needle 36 and the spring male needle 34 into the needle holes 33 on the spring female needle holder 31 and the spring male needle holder 32 respectively; then inserting the needle holder protrusions 35 on the spring female needle holder 31 and the spring male needle holder 32 into the connecting hole 22 on the circuit board 2; and then welding and fixing (during welding, keep the spring female needle 36 and the spring male needle 34 at the same level to ensure the accuracy of later electrical connection); and

step III. putting magnets 45 into the magnet grooves 44 (the fixed direction of magnetic attraction shall be considered by the installation manner); then putting the circuit board 2 welded in step II onto the bottom plate 4; and finally, inserting the second connecting protrusions 13 at the bottom of the structural element 1 into the magnet grooves 44, and welding and fixing by an ultrasonic welding machine.

For those skilled in the art, apparently, the present invention is not limited to details of the above demonstrative embodiments. Moreover, the present invention can be realized in other specific forms without departing from the spirit or basic feature of the present invention. Therefore, in all respects, the embodiments shall be regarded to be demonstrative and nonrestrictive. The scope of the present invention is defined by appended claims, rather than the above description. Therefore, the present invention is intended to include all changes falling into the meaning and the scope of equivalent elements of claims within the present invention. Any drawing mark in claims shall not be regarded to limit the concerned claims.

In addition, it shall be understood that although the description is explained in accordance with the embodiments, not every embodiment only includes one independent technical solution. This narration mode of the description is only for clarity. Those skilled in the art shall regard the description as a whole, and the technical solution in each embodiment can also be appropriately combined to form other embodiments understandable for those skilled in the art.

What is claimed is:

1. A magnetic attraction type electronic building block construction module, comprising a circuit board, wherein the circuit board comprises a circuit board body; the circuit board body is provided with a connecting hole; a spring needle holder is installed on the bottom of the circuit board; the spring needle holder comprises a spring female needle holder and a spring male needle holder; upper ends of the spring female needle holder and the spring male needle holder are fixedly provided with needle holder protrusions matched with the connecting hole; a bottom plate is installed on the bottom of the spring needle holder; the bottom plate comprises a bottom plate body; bottom plate upper protrusions are fixedly installed around the upper surface of the bottom plate body; magnet grooves are formed in the upper surfaces of the bottom plate upper protrusions; magnets are installed in the magnet grooves; a structural element is installed on the upper end of the circuit board; the structural element comprises a structural element body; and second connecting protrusions matched with the magnet grooves are fixedly installed on the bottom of the structural element body.

2. The magnetic attraction type electronic building block construction module according to claim 1, wherein needle holes are formed in the spring female needle holder and the spring male needle holder; spring female needles matched with the needle holes are installed in the needle holes of the spring female needle holder; and spring male needles matched with the needle holes are installed in the needle holes of the spring male needle holder.

3. The magnetic attraction type electronic building block construction module according to claim 1, wherein the spring needle holder is welded with the circuit board.

4. The magnetic attraction type electronic building block construction module according to claim 3, wherein the structural element and the bottom plate are made of plastic.

5. The magnetic attraction type electronic building block construction module according to claim 3, wherein the structural element and the bottom plate are connected through ultrasonic welding.

6. The magnetic attraction type electronic building block construction module according to claim 3, wherein a connecting interface is arranged on a side surface of the structural element body.

7. The magnetic attraction type electronic building block construction module according to claim 6, wherein the upper end of the structural element body is also fixedly provided with first connecting protrusions; bottom plate lower protrusions are fixedly installed around the bottom of the bottom plate body; and grooves matched with the first connecting protrusions are formed at the bottoms of the bottom plate lower protrusions.

8. A manufacturing method of the magnetic attraction type electronic building block construction module of claim 1, comprising the following steps:
step I. selecting a matching component according to a design size;
step II. inserting the spring female needle and the spring male needle into the needle holes of the spring female needle holder and the spring male needle holder respectively; then inserting the needle holder protrusions on the spring female needle holder and the spring male needle holder into the connecting hole on the circuit board; and then welding and fixing; and
step III. putting magnets into the magnet grooves; then putting the circuit board welded in step II onto the bottom plate; and finally, inserting the second connecting protrusions at the bottom of the structural element into the magnet grooves, and welding and fixing by an ultrasonic welding machine.
